(19) United States
(12) Patent Application Publication
(10) Pub. No.: US 2023/0187204 A1
(43) Pub. Date: Jun. 15, 2023

(54) Tungsten Fluoride Soak And Treatment For Tungsten Oxide Removal

(71) Applicant: Applied Materials, Inc., Santa Clara, CA (US)

(72) Inventors: Xiaodong Wang, San Jose, CA (US); Kevin Kashefi, San Ramon, CA (US); Rongjun Wang, Dublin, CA (US); Shi You, San Jose, CA (US); Keith T. Wong, Mountain View, CA (US); Yuchen Liu, San Jose, CA (US); Ya-Hsi Hwang, Sunnyvale, CA (US); Jean Lu, Palo Alto, CA (US)

(73) Assignee: Applied Materials, Inc., Santa Clara, CA (US)

(21) Appl. No.: 17/844,189

(22) Filed: Jun. 20, 2022

Related U.S. Application Data
(60) Provisional application No. 63/288,077, filed on Dec. 10, 2021.

(51) Int. Cl. H01L 21/02; H01L 21/285

(52) U.S. Cl. CPC H01L 21/0234; H01L 21/28568

(57) ABSTRACT

Provided are methods for pre-cleaning a substrate. A substrate having tungsten oxide (WOₓ) thereon is soaked in tungsten fluoride (WF₆), which reduces the tungsten oxide (WOₓ) to tungsten (W). Subsequently, the substrate is treated with hydrogen, e.g., plasma treatment or thermal treatment, to reduce the amount of fluorine present so that fluorine does not invade the underlying insulating layer.

### CROSS-REFERENCE TO RELATED APPLICATIONS

This application claims priority to U.S. Provisional Application No. 63/288,077, filed Dec. 10, 2021, the entire disclosure of which is hereby incorporated by reference herein.

### TECHNICAL FIELD

Embodiments of the present disclosure pertain to the field of electronic devices and methods and apparatus for manufacturing electronic devices. More particularly, embodiments of the disclosure provide methods for pre-cleaning a substrate.

### BACKGROUND

Generally, an integrated circuit (IC) refers to a set of electronic devices, e.g., transistors formed on a small chip of semiconductor material, typically, silicon. Typically, the IC includes one or more layers of metallization having metal lines to connect the electronic devices of the IC to one another and to external connections. Typically, layers of the interlayer dielectric material are placed between the metallization layers of the IC for insulation.

During back end of the line (BEOL) processing the individual devices, e.g., transistors, capacitors, resistors, and the like, are interconnected with wiring on the wafer. Pre-clean and/or etching processes can lead to the presence of fluorine in the low-k dielectric layer, which can cause carbon loss in the low-k dielectric layer.

Thus, there is a need for methods that minimize the fluorine content of the dielectric layer of a semiconductor structure.

### SUMMARY

One or more embodiments of the disclosure are directed to a method of treating a substrate. The method comprises soaking a substrate comprising tungsten oxide (WOₓ) in tungsten fluoride (WF₆) to reduce the tungsten oxide (WOₓ) to form tungsten (W) at a temperature greater than or equal to 300° C.; and treating the substrate with a plasma comprising hydrogen (H₂), helium (He), and argon (Ar).

Additional embodiments are directed to a method of treating a substrate. In one or more embodiments, the method comprises: soaking a substrate comprising tungsten oxide (WOₓ) in tungsten fluoride (WF₆) to reduce the tungsten oxide (WOₓ) to form tungsten (W) at a temperature greater than or equal to 300° C.; and flowing a stream of hydrogen (H₂) gas over the substrate at a temperature greater than or equal to 350° C.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method according to one or more embodiments of the disclosure;

FIG. 2A illustrates a cross-sectional view of an exemplary substrate during processing according to one or more embodiments of the disclosure;

FIG. 2B illustrates a cross-sectional view of an exemplary substrate during processing according to one or more embodiments of the disclosure;

FIG. 2C illustrates a cross-sectional view of an exemplary substrate during processing according to one or more embodiments of the disclosure; and

FIG. 3 illustrates a process flow diagram of a method according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process act. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates.

The term “over” as used herein does not imply a physical orientation of one surface on top of another surface, rather a relationship of the thermodynamic or kinetic properties of the chemical reaction with one surface relative to the other surface. For example, selectively depositing a film onto a damaged dielectric material over an oxide material means that the film deposits on the damaged dielectric material and less or no film deposits on the oxide material; or that the formation of the film on the damaged dielectric material is thermodynamically or kinetically favorable relative to the formation of a film on the oxide material.

As used in this specification and the appended claims, the terms “precursor”, “reactant”, “reactive gas” and the like are used interchangeably to refer to any gaseous species that can react with the substrate surface.

Embodiments of the present disclosure relate to methods for pre-cleaning a substrate. In one or more embodiments, a substrate having tungsten oxide (WOₓ) thereon is soaked in tungsten fluoride (WF₆), which reduces the tungsten oxide (WOₓ) to tungsten (W). Subsequently, the substrate is advantageously treated with hydrogen, e.g., plasma treatment or thermal treatment, to reduce the amount of fluorine present so that fluorine does not invade the underlying dielectric layer.

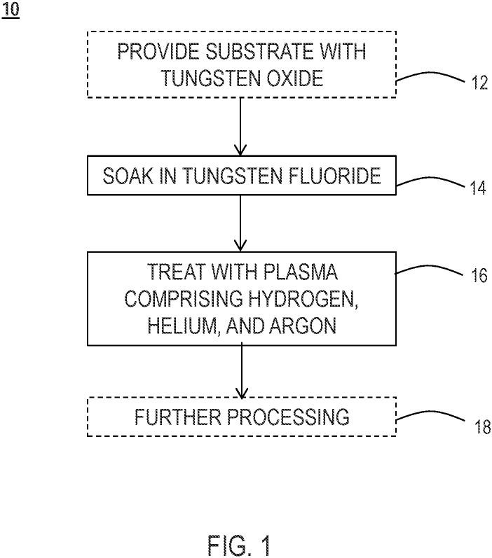

FIG. 1 depicts a generalized method 10 for forming pre-cleaning a substrate in accordance with one or more embodiments of the disclosure. The method 10 generally begins at operation 12, where a substrate having tungsten oxide (WOₓ) thereon is provided and placed into a processing chamber. At operation 14, the substrate having the tungsten oxide (WOₓ) thereon is soaked in tungsten fluoride (WF₆) to reduce the tungsten oxide to tungsten (W). At operation 16, the substrate is treated with a hydrogen plasma. The method 10 then moves to an optional post-processing operation 18.

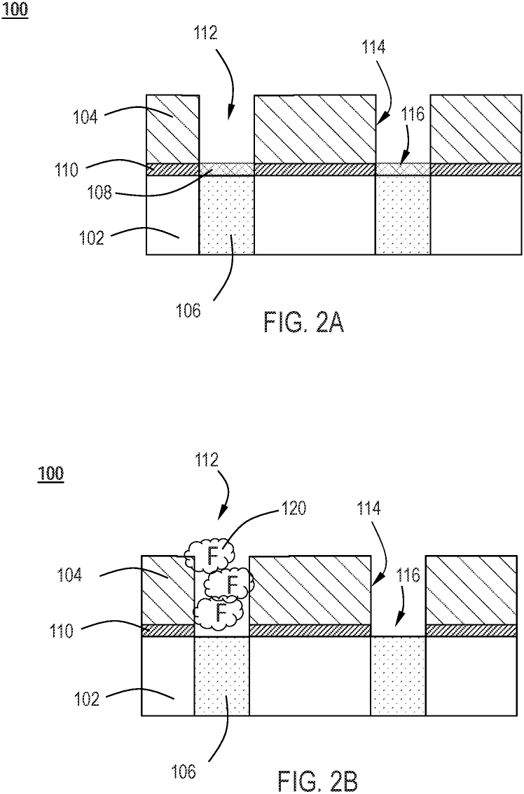

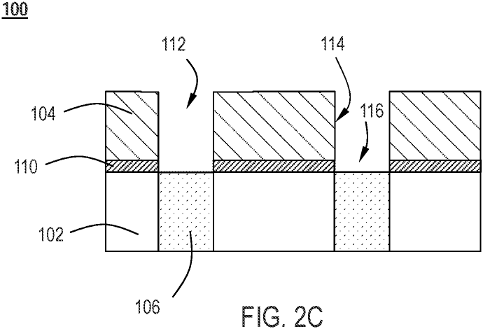

FIGS. 2A to 2C illustrate cross-section views of an exemplary device 100 during the treatment. With reference to FIG. 1 and FIG. 2A, at operation 12, a substrate 102 having an insulating layer 104 thereon is provided. As used in this specification and the appended claims, the term “provided” means that the substrate or substrate surface is made available for processing (e.g., positioned in a processing chamber). In some embodiments, an etch stop layer 110 is on the top surface of the substrate 102 between the substrate 102 and the insulating layer 104.

In one or more embodiments, the etch stop layer 110 may comprise any suitable material known to the skilled artisan. In one or more embodiments, the etch stop layer 110 may comprise one or more of silicon nitride (SiN), silicon carbide (SiC), aluminum oxide (AlOₓ), and aluminum nitride (AIN). In some embodiments, the etch stop layer 110 may be deposited using a technique selected from CVD, PVD, and ALD.

In one or more embodiments, the insulating layer 104 may comprise any suitable material known to the skilled artisan. As used herein, the term “insulating layer” or “insulating material” or the like refers any material suitable to insulate adjacent devices and prevent leakage. In one or more embodiments, the insulating layer 104 comprises a dielectric material. As used herein, the term “dielectric material” refers to an electrical insulator that can be polarized in an electric field. In some embodiments, the dielectric material comprises one or more of oxides, carbon doped oxides, silicon dioxide (SiO₂), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH). In some embodiments, the insulating layer 104 comprises a low-k dielectric material. In one or more embodiments, the insulating layer 104 is a low-_{K} dielectric that includes, but is not limited to, materials such as, e.g., silicon oxide, carbon doped oxide (“CDO”), e.g., carbon doped silicon dioxide, porous silicon dioxide (SiO₂), silicon nitride (SiN), silicon carbide (SiC), or any combination thereof. In one or more embodiments, the insulating layer 104 includes one or more of silicon oxide (SiOₓ), silicon nitride (SiN), silicon carbide (SiC), silicon oxycarbide (SiOC), and the like.

In one or more embodiments, the insulating layer 104 includes a dielectric material having a K-value less than 5. In one or more embodiments, insulating layer 104 includes a dielectric material having a K-value less than 3. In at least some embodiments, the insulating layer 104 includes oxides, carbon doped oxides, porous silicon dioxide, carbides, oxycarbides, nitrides, oxynitrides, oxycarbonitrides, polymers, phosphosilicate glass, fluorosilicate (SiOF) glass, organosilicate glass (SiOCH), or any combinations thereof, other electrically insulating materials determined by an electronic device design, or any combination thereof.

In one or more embodiments, the insulating layer 104 is a low-_{K} dielectric to isolate one metallization layer or metal line from other metal lines on the substrate 102. In one or more embodiments, the thickness of the insulating layer 104 is in an approximate range from about 10 nanometers (nm) to about 2 microns (µm).

In an embodiment, the insulating layer 104 is deposited using one of deposition techniques, such as but not limited to a chemical vapor deposition (“CVD”), a physical vapor deposition (“PVD”), molecular beam epitaxy (“MBE”), metalorganic chemical vapor deposition (“MOCVD”), atomic layer deposition (“ALD”), spin-on, or other insulating deposition techniques known to one of ordinary skill in the art of microelectronic device manufacturing.

In some embodiments, an etch stop layer 110 is deposited on the top surface of the substrate 102 and the metallization layer 106. In some embodiments, not illustrated, a mask layer is formed on the insulating layer 104. The insulating layer 104 may by etched to form the opening 112, the at least one opening 112 having a bottom surface 116 comprising an exposed portion of the etch stop layer 110. In one or more embodiments, the etch stop layer 110 exposed through the opening 112 is selectively removed so that the bottom surface 116 of the opening 112 comprises the metallization layer 106, as illustrated in FIG. 2A.

In one or more embodiments, the insulating layer 104 has an opening 112 extending from a top surface of the insulating layer 104 to a metallization layer 106. In one or more embodiments, the opening 112 has at least one sidewall 114 and a bottom surface 116. In some embodiments, the opening 112 may be referred to as a via opening or a trench.

As used herein, the term “aspect ratio” of an opening, a trench, a via, and the like refers to the ratio of the depth of the opening to the width of the opening. In one or more embodiments, the aspect ratio of each opening 112, is in an approximate range from about 1:1 to about 200:1. In some embodiments, the aspect ratio of the opening 112 is at least 2:1. In other embodiments, the aspect ratio of the opening 112 is at least 5:1, or at least 10:1.

The metallization layer 106 may have any suitable thickness. In some embodiments, the metallization layer 106 has a thickness in a range of from 1 nm to 10 µm.

In one or more embodiments, the metallization layer 106 comprises tungsten (W). In one or more embodiments, the metallization layer 106 has a layer of oxide 108 thereon. In one or more embodiments, the oxide layer 108 comprises a tungsten oxide (WOₓ) layer. While the tungsten oxide layer 108 is drawn as a continuous layer, it will be appreciated by one of skill in the art that the tungsten oxide layer 108 may be not be a continuous layer but instead may be discrete particles of tungsten oxide. In one or more embodiments, the tungsten oxide layer 108 comprises tungsten oxide (WOₓ).

Referring to FIG. 1 and FIG. 2B, at operation 14, the device 100 is soaked in tungsten fluoride (WF₆) to reduce the tungsten oxide layer 108 to tungsten (W) metal, thus removing the tungsten oxide layer 108. Without intending to be bound by theory, it is thought that the soaking treatment results in the formation of excess fluorine 120 on the device 100. In one or more embodiments, the excess fluorine 120 can extend to the insulating layer 104. In some embodiments, the excess fluorine 120 can lead to significant carbon loss.

In one or more embodiments, the soaking treatment may have any suitable pressure. In one or more embodiments, the device 100 is soaked in tungsten fluoride (WF₆) at a pressure in a range of from 0.2 Torr to less than 20 Torr, or in a range of from 0.2 Torr to 15 Torr, or in a range of from 0.2 Torr to 10 Torr.

In one or more embodiments, the soaking treatment may occur for any suitable period of time. In one or more embodiments, the device 100 is soaked in tungsten fluoride for a period of time in a range of from 1 second to 10 minutes, or in a range of from 1 second to 5 minutes, or in a range of from 10 seconds to 5 min, or in a range of from 10 seconds to 3 minutes, or in a range of from 10 seconds to 2 minutes, or in a range of from 30 sec to 2 minutes.

In one or more embodiments, the soaking treatment may occur with any suitable flow rate. In one or more embodiments, the substrate may be soaked in the tungsten fluoride with the tungsten fluoride having a flow rate in a range of from 1 sccm to 500 sccm, or in a range of from 10 sccm to 400 sccm, or in a range of from 10 sccm to 300 sccm, or in a range of from 10 sccm to 200 sccm.

In one or more embodiments, the substrate may be soaked in tungsten fluoride combined or co-flowed with an inert gas. In some embodiments, the inert gas may be selected from one or more of helium (He), argon (Ar), xenon (Xe). In specific embodiments, the inert gas is argon (Ar). In one or more embodiments, the substrate is soaked in tungsten fluoride combined or co-flowed with an inert gas having a flow rate in a range of from 10 sccm to 10,000 sccm, or in a range of from 10 sccm to 9000 sccm, or in a range of from 100 sccm to 8000 sccm, or in a range of from 100 sccm to 7000 sccm.

In one or more embodiments, the soaking treatment may occur at any suitable temperature. In one or more embodiments, the temperature is greater than or equal to 300° C., or greater than or equal to 325° C., or greater than or equal to 330° C., or greater than or equal to 335° C., or greater than or equal to 340° C., or greater than or equal to 345° C., or greater than or equal to 350° C. In one or more embodiments, the temperature is in a range of from 300° C. to 750° C., or in a range of from 325° C. to 750° C.

With reference to FIG. 1 and FIG. 2C, at operation 16, the device 100 is treated with a plasma at a temperature in a range of from greater than 300° C. to 1000° C. to reduce or remove the excess fluorine 120 that is present and form an insulation layer 104 that is substantially free of fluoride. As used herein, the term “substantially free” means that there is less than 5%, including less than 4%, less than 3%, less than 2%, less than 1%, and less than 0.5% of fluorine in or on the insulation layer 104.

In one or more embodiments, the plasma comprises a mixture of hydrogen (H₂), argon (Ar), and helium (He). The hydrogen (H₂), argon (Ar), and helium (He) may be present in any suitable ratio. In some embodiments, the argon (Ar) and helium (He) comprise the majority of the plasma. In one or more embodiments, the hydrogen (H₂), argon (Ar), and helium (He) are present in the plasma in a ratio of hydrogen (H₂) to argon (Ar) and helium (He) of about 1:1. In other embodiments, the hydrogen (H₂), argon (Ar), and helium (He) are present in the plasma in a ratio of hydrogen (H₂) to argon (Ar) and helium (He) of greater than 1:1, or greater than 1:1.1, or greater than 1:1.2, or greater than 1:1.3, or greater than 1:1.4, or greater than 1:1.5, or greater than 1:1.6, or greater than 1:1.7, or greater than 1:1.8, or greater than 1:1.9, or greater than 1:2, or greater than 1:3, or greater than 1:5, or greater than 1:7, or greater than 1:10, or greater than 1:20, or greater than 1:50, or greater than 1 :100.

The hydrogen (H₂) plasma may have any suitable flow rate. In one or more embodiments, hydrogen (H₂) plasma has a plasma has a flow rate in a range of from 1 sccm to 1000 sccm, or in a range of from 1 sccm to 500 sccm, or in a range of from 1 sccm to 400 sccm, or in a range of from 1 sccm to 300 sccm, or in a range of from 1 sccm to 200 sccm, or in a range of from 1 sccm to 150 sccm, or in a range of from 1 sccm to 50 sccm, or in a range of from 1 sccm to 40 sccm, or in a range of from 1 sccm to 30 sccm, or in a range of from 1 sccm to 20 sccm, or in a range of from 1 sccm to 10 sccm.

The argon (Ar) plasma may have any suitable flow rate. In one or more embodiments, the argon (Ar) plasma has a flow rate in a range of from 1 sccm to 1000 sccm, or in a range of from 1 sccm to 500 sccm, or in a range of from 1 sccm to 400 sccm, or in a range of from 1 sccm to 300 sccm, or in a range of from 1 sccm to 200 sccm, or in a range of from 1 sccm to 150 sccm, or in a range of from 1 sccm to 50 sccm, or in a range of from 1 sccm to 40 sccm, or in a range of from 1 sccm to 30 sccm, or in a range of from 1 sccm to 20 sccm, or in a range of from 1 sccm to 10 sccm.

The helium (He) plasma may have any suitable flow rate. In one or more embodiments, the helium (He) plasma has a flow rate in a range of from 1 sccm to 1000 sccm, or in a range of from 1 sccm to 500 sccm, or in a range of from 1 sccm to 400 sccm, or in a range of from 1 sccm to 300 sccm, or in a range of from 1 sccm to 200 sccm, or in a range of from 1 sccm to 150 sccm, or in a range of from 1 sccm to 50 sccm, or in a range of from 1 sccm to 40 sccm, or in a range of from 1 sccm to 30 sccm, or in a range of from 1 sccm to 20 sccm, or in a range of from 1 sccm to 10 sccm.

In one or more embodiments, the plasma treatment may occur at any suitable pressure. In one or more embodiments, the device 100 is treated with the plasma at a pressure in a range of from 0.2 mTorr to less than 500 mTorr, or in a range of from 0.2 mTorr to 400 mTorr, or in a range of from 0.2 mTorr to 300 mTorr, or in a range of from 0.2 mTorr to 250 mTorr, or in a range of from 10 mTorr to 200 mTorr, or in a range of from 10 mTorr to 100 mTorr. In some embodiments, the pressure is greater than 50 mTorr, or greater than 60 mTorr, or greater than 70 mTorr, or greater than 80 mTorr, or greater than 90 mTorr, or greater than 100 mTorr.

In one or more embodiments, the plasma treatment may occur for any suitable period of time. In one or more embodiments, the device 100 is treated with the plasma for a period of time in a range of from 10 seconds to 10 minutes, or in a range of from 10 seconds to 5 minutes, or in a range of from 10 seconds to 4.5 min, or in a range of from 10 seconds to 3 minutes, or in a range of from 10 seconds to 2 minutes, or in a range of from 30 sec to 2 minutes.

In some embodiments, the plasma gas is flowed into the processing chamber and then ignited to form a direct plasma. In some embodiments, the plasma gas is ignited outside of the processing chamber to form a remote plasma.

In some embodiments, the plasma is an inductively coupled plasma (ICP). In some embodiments, the plasma is a conductively coupled plasma (CCP). In some embodiments, the plasma is a microwave plasma. In some embodiments, the plasma is generated by passing the plasma gas over a hot wire.

In one or more embodiments, the plasma treatment may occur at any suitable power. In one or more embodiments, the power is in a range of from 10 W to 2000 W, or in a range of from 100 W to 1500 W, or in a range of from 100 W to 1000 W, or in a range of from 100 W to 750 W.

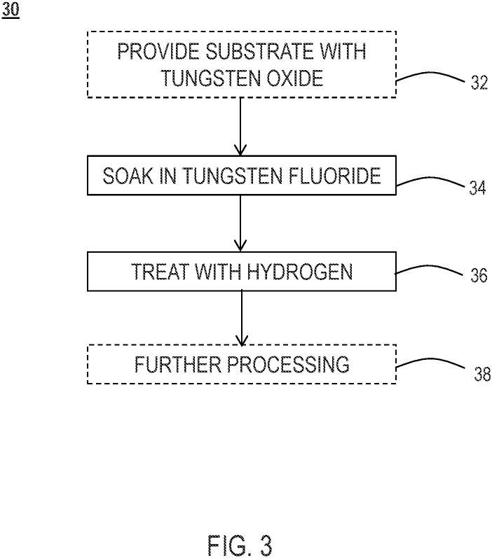

FIG. 3 depicts an alternative generalized method 30 for forming pre-cleaning a substrate in accordance with one or more embodiments of the disclosure. The method 10 generally begins at operation 32, where a substrate 102 having tungsten oxide (WOₓ) thereon is provided and placed into a processing chamber. At operation 34, the substrate having the tungsten oxide (WOₓ) thereon is soaked in tungsten fluoride (WF₆) to reduce the tungsten oxide to tungsten (W). At operation 36, the substrate is treated thermally with hydrogen. The method 30 then moves to an optional post-processing operation 38.

With reference to FIG. 3 and FIG. 2A, at operation 32, a substrate 102 having an insulating layer 104 thereon is provided.

In some embodiments, an etch stop layer 110 is on the top surface of the substrate 102 between the substrate 102 and the insulating layer 104.

In one or more embodiments, the etch stop layer 110 may comprise any suitable material known to the skilled artisan. In one or more embodiments, the etch stop layer 110 may comprise one or more of silicon nitride (SiN), silicon carbide (SiC), aluminum oxide (AlOₓ), and aluminum nitride (AIN). In some embodiments, the etch stop layer 110 may be deposited using a technique selected from CVD, PVD, and ALD.

In one or more embodiments, the insulating layer 104 may comprise any suitable material known to the skilled artisan. In some embodiments, the insulating layer 104 comprises a low-k dielectric material. In one or more embodiments, the insulating layer 104 is a low-_{K} dielectric that includes, but is not limited to, materials such as, e.g., silicon oxide, carbon doped oxide (“CDO”), e.g., carbon doped silicon dioxide, porous silicon dioxide (SiO₂), silicon nitride (SiN), silicon carbide (SiC), or any combination thereof. In one or more embodiments, the insulating layer 104 includes one or more of silicon oxide (SiOₓ), silicon nitride (SiN), silicon carbide (SiC), silicon oxycarbide (SiOC), and the like.

In one or more embodiments, the insulating layer 104 includes a dielectric material having a K-value less than 5. In one or more embodiments, insulating layer 104 includes a dielectric material having a K-value less than 3. In at least some embodiments, the insulating layer 104 includes oxides, carbon doped oxides, porous silicon dioxide, carbides, oxycarbides, nitrides, oxynitrides, oxycarbonitrides, polymers, phosphosilicate glass, fluorosilicate (SiOF) glass, organosilicate glass (SiOCH), or any combinations thereof, other electrically insulating materials determined by an electronic device design, or any combination thereof.

In one or more embodiments, the insulating layer 104 is a low-_{K} dielectric to isolate one metallization layer or metal line from other metal lines on the substrate 102. In one or more embodiments, the thickness of the insulating layer 104 is in an approximate range from about 10 nanometers (nm) to about 2 microns (µm).

In some embodiments, an etch stop layer 110 is deposited on the top surface of the substrate 102 and the metallization layer 106. In some embodiments, not illustrated, a mask layer is formed on the insulating layer 104. The insulating layer 104 may by etched to form the opening 112, the at least one opening 112 having a bottom surface 116 comprising an exposed portion of the etch stop layer 110. In one or more embodiments, the etch stop layer 110 exposed through the opening 112 is selectively removed so that the bottom surface 116 of the opening 112 comprises the metallization layer 106, as illustrated in FIG. 2A.

In one or more embodiments, the insulating layer 104 has an opening 112 extending from a top surface of the insulating layer 104 to a metallization layer 106. In one or more embodiments, the opening 112 has at least one sidewall 114 and a bottom surface 116. In some embodiments, the opening 112 may be referred to as a via opening or a trench.

In one or more embodiments, the metallization layer 106 comprises tungsten (W). In one or more embodiments, the metallization layer 106 has a layer of oxide 108 thereon. In one or more embodiments, the oxide layer 108 comprises a tungsten oxide (WOₓ) layer. While the tungsten oxide layer 108 is drawn as a continuous layer, it will be appreciated by one of skill in the art that the tungsten oxide layer 108 may be not be a continuous layer but instead may be discrete particles of tungsten oxide. In one or more embodiments, the tungsten oxide layer 108 comprises tungsten oxide (WOₓ).

Referring to FIG. 3 and FIG. 2B, at operation 34,

the device 100 is soaked in tungsten fluoride (WF₆) to reduce the tungsten oxide layer 108 to tungsten (W) metal, thus removing the tungsten oxide layer 108. Without intending to be bound by theory, it is thought that the soaking treatment results in the formation of excess fluorine 120 on the device 100. In one or more embodiments, the excess fluorine 120 can extend to the insulating layer 104. In some embodiments, the excess fluorine 120 can lead to significant carbon loss.

In one or more embodiments, the soaking treatment may have any suitable pressure. In one or more embodiments, the device 100 is soaked in tungsten fluoride (WF₆) at a pressure in a range of from 0.2 Torr to less than 20 Torr, or in a range of from 0.2 Torr to 15 Torr, or in a range of from 0.2 Torr to 10 Torr.

In one or more embodiments, the soaking treatment may occur for any suitable period of time. In one or more embodiments, the device 100 is soaked in tungsten fluoride for a period of time in a range of from 1 second to 10 minutes, or in a range of from 1 second to 5 minutes, or in a range of from 10 seconds to 5 min, or in a range of from 10 seconds to 3 minutes, or in a range of from 10 seconds to 2 minutes, or in a range of from 30 sec to 2 minutes.

In one or more embodiments, the soaking treatment may occur with any suitable flow rate. In one or more embodiments, the substrate may be soaked in the tungsten fluoride with the tungsten fluoride having a flow rate in a range of from 1 sccm to 500 sccm, or in a range of from 10 sccm to 400 sccm, or in a range of from 10 sccm to 300 sccm, or in a range of from 10 sccm to 200 sccm.

In one or more embodiments, the substrate may be soaked in tungsten fluoride combined or co-flowed with an inert gas. In some embodiments, the inert gas may be selected from one or more of helium (He), argon (Ar), xenon (Xe). In specific embodiments, the inert gas is argon (Ar). In one or more embodiments, the substrate is soaked in tungsten fluoride combined or co-flowed with an inert gas having a flow rate in a range of from 10 sccm to 10,000 sccm, or in a range of from 10 sccm to 9000 sccm, or in a range of from 100 sccm to 8000 sccm, or in a range of from 100 sccm to 7000 sccm.

In one or more embodiments, the soaking treatment may occur at any suitable temperature. In one or more embodiments, the temperature is greater than or equal to 300° C., or greater than or equal to 325° C., or greater than or equal to 330° C., or greater than or equal to 335° C., or greater than or equal to 340° C., or greater than or equal to 345° C., or greater than or equal to 350° C. In one or more embodiments, the temperature is in a range of from 300° C. to 750° C., or in a range of from 325° C. to 750° C.

With reference to FIG. 3 and FIG. 2C, at operation 36, the device 100 is thermally treated with hydrogen (H₂) gas at a temperature in a range of from greater than 300° C. to 1000° C. to reduce or remove the excess fluorine 120 that is present and form an insulating layer 104 that is substantially free of fluorine. As used herein, the term “substantially free” means that there is less than 5%, including less than 4%, less than 3%, less than 2%, less than 1%, and less than 0.5% of fluorine in or on the insulating layer 104.

In one or more embodiments, the hydrogen (H₂) gas may be mixed with an inert gas. The inert has may comprise any suitable inert gas including, but not limited to, argon (Ar), helium (He), and xenon (Xn).

In one or more embodiments, the hydrogen (H₂) gas may have any suitable flow rate. In one or more embodiments, hydrogen (H₂) gas has a flow rate in a range of from 1 sccm to 1000 sccm, or in a range of from 1 sccm to 500 sccm, or in a range of from 1 sccm to 400 sccm, or in a range of from 1 sccm to 300 sccm, or in a range of from 1 sccm to 200 sccm, or in a range of from 1 sccm to 150 sccm, or in a range of from 1 sccm to 50 sccm, or in a range of from 1 sccm to 40 sccm, or in a range of from 1 sccm to 30 sccm, or in a range of from 1 sccm to 20 sccm, or in a range of from 1 sccm to 10 sccm.

In one or more embodiments, the inert gas may have any suitable flow rate. In one or more embodiments, the inert gas has a flow rate in a range of from 1 sccm to 1000 sccm, or in a range of from 1 sccm to 500 sccm, or in a range of from 1 sccm to 400 sccm, or in a range of from 1 sccm to 300 sccm, or in a range of from 1 sccm to 200 sccm, or in a range of from 1 sccm to 150 sccm, or in a range of from 1 sccm to 50 sccm, or in a range of from 1 sccm to 40 sccm, or in a range of from 1 sccm to 30 sccm, or in a range of from 1 sccm to 20 sccm, or in a range of from 1 sccm to 10 sccm.

In one or more embodiments, the hydrogen treatment may occur at any suitable pressure. In one or more embodiments, the device 100 is treated with hydrogen at a pressure in a range of from 10 mTorr to 1000 Torr, or in a range of from 100 mTorr to 900 Torr, or in a range of from 100 mTorr to 800 Torr, or in a range of from 100 mTorr to 760 Torr.

In one or more embodiments, the hydrogen treatment may occur for any suitable period of time. In one or more embodiments, the device 100 is treated with hydrogen for a period of time in a range of from 10 seconds to 10 minutes, or in a range of from 10 seconds to 5 minutes, or in a range of from 10 seconds to 4.5 min, or in a range of from 10 seconds to 3 minutes, or in a range of from 10 seconds to 2 minutes, or in a range of from 30 sec to 2 minutes.

Several well-known cluster tools which may be adapted for the present disclosure are the Olympia®, the Continuum®, and the Trillium®, all available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), plasma treatment, etch, pre-clean, chemical clean, thermal treatment such as RTP, plasma nitridation, degas, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of treating a substrate, the method comprising:
soaking a substrate comprising tungsten oxide (WOₓ) in tungsten fluoride (WF₆) to reduce the tungsten oxide (WOₓ) to form tungsten (W) at a temperature greater than or equal to 300° C.; and
treating the substrate with a plasma comprising hydrogen (H₂), helium (He), and argon (Ar).

2. The method of claim 1, wherein the substrate is soaked in tungsten fluoride (WF₆) at a temperature greater than or equal to 325° C.

3. The method of claim 1, wherein the substrate is soaked in tungsten fluoride (WF₆) at a temperature greater than or equal to 345° C.

4. The method of claim 1, where the substrate is soaked in tungsten fluoride (WF₆) for a period of time in a range of from 1 second to 5 min.

5. The method of claim 1, wherein the plasma has a ratio of hydrogen (H₂) to helium (He) and argon (Ar) of greater than 1:1.

6. The method of claim 5, wherein the ratio is greater than 1:2.

7. The method of claim 5, wherein the ratio is greater than 1:20.

8. The method of claim 1, wherein the tungsten oxide (WOₓ) is formed on an insulating layer.

9. The method of claim 8, wherein the insulating layer comprises a low-k material.

10. The method of claim 9, wherein treating the substrate with the plasma does not increase a concentration of fluorine in the low-k material.

11. The method of claim 1, wherein the plasma has a pressure in a range of from 10 mTorr to 500 mTorr.

12. A method of treating a substrate, the method comprising:
soaking a substrate comprising tungsten oxide (WOₓ) in tungsten fluoride (WF₆) to reduce the tungsten oxide (WOₓ) to form tungsten (W) at a temperature greater than or equal to 300° C.; and
flowing a stream of hydrogen (H₂) gas over the substrate at a temperature greater than or equal to 350° C.

13. The method of claim 12, wherein the substrate is soaked in tungsten fluoride (WF₆) at a temperature greater than or equal to 325° C.

14. The method of claim 12, wherein the substrate is soaked in tungsten fluoride (WF₆) at a temperature greater than or equal to 345° C.

15. The method of claim 12, wherein the hydrogen (H₂) gas is co-flowed with an inert gas.

16. The method of claim 15, wherein the inert gas is selected from one or more of helium (He), argon (Ar), and xenon (Xn).

17. The method of claim 12, wherein the tungsten oxide (WOₓ) is formed on an insulating layer.

18. The method of claim 17, wherein the insulating layer comprises a low-k material.

19. The method of claim 18, wherein treating the substrate with the plasma does not increase a concentration of fluorine in the low-k material.

20. The method of claim 12, wherein the hydrogen (H₂) gas is flowed over the substrate at a temperature greater than or equal to 450° C.
